(19) United States
(12) Patent Application Publication
(10) Pub. No.: US 2026/0173501 A1
(43) Pub. Date: Jun. 18, 2026

(54) SUPERJUNCTION METAL-OXIDE-SEMICONDUCTOR FIELD-EFFECT TRANSISTOR

(71) Applicant: POTENS SEMICONDUCTOR CORP., Hsinchu County (TW)

(72) Inventors: Hamilton Lu, Los Angeles, CA (US); Tung Ming Lai, Hsinchu County (TW); Hsiang Chi Meng, Hsinchu County (TW); Yung Sheng Ko, Hsinchu County (TW)

(73) Assignee: POTENS SEMICONDUCTOR CORP., Hsinchu County (TW)

(21) Appl. No.: 19/195,911

(22) Filed: May 1, 2025

(30) Foreign Application Priority Data
Dec. 18, 2024 (TW) 113149490

(51) Int. Cl. H10D 84/00; H10D 8/50; H10D 30/66; H10D 62/10; H10D 62/60; H10D 62/832; H10D 62/834

(52) U.S. Cl. CPC H10D 84/141; H10D 8/50; H10D 30/66; H10D 62/103; H10D 62/124; H10D 62/60; H10D 62/8325; H10D 62/834

(57) ABSTRACT

The present disclosure is related to a superjunction metal-oxide-semiconductor field-effect transistor (MOSFET). First, a P-type semiconductor and an N-type semiconductor with high doping concentrations are embedded in an N-type drift layer through ion implantation. The P-type semiconductor and the N-type semiconductor form an I-type junction at their interface. Energy levels of intra-band and inter-band quantum states generated at the I-type junction can absorb carriers generated in the device after irradiation, and tunneling electrons between the P-type semiconductor and the N-type semiconductor. This, combined with an effect of overlapping synchronized quantum states, causes a large number of quantum state energy levels to be created to absorb carriers, thereby effectively enhancing radiation resistance of the device. Additionally, the PIN diode can be embedded at different positions within the N-type drift layer, allowing superjunction MOSFETs to exhibit varying radiation resistance capabilities and on-resistance, to meet optimal requirements of various applications.

### CROSS-REFERENCE TO RELATED APPLICATION

The present disclosure claims priority to a Taiwan Patent Application No. 113149490 filed on Dec. 18, 2024, the disclosure of which is incorporated in its entirety by reference herein.

### BACKGROUND OF THE DISCLOSURE

### Field of the Disclosure

The present disclosure particularly relates to a superjunction metal-oxide-semiconductor field-effect transistor (MOSFET) in which a PIN diode is embedded through ion implantation to enhance radiation resistance.

### Brief Description of Related Art

With the rise of space technology and the advancement of nuclear technology, damage caused by radiation or charged particles to semiconductor devices and preventive measures thereof have become increasingly important research topics. Referring to FIG. 1, when a metal-oxide-semiconductor field-effect transistor (MOSFET) is exposed to an environment of high-intensity radiation rays R, ionization occurs within a semiconductor structure, leading to generation of electron-hole (e-h) pairs. These e-h pairs are easily trapped by defect structures within the device. The defect structures include an interface between a semiconductor and a dielectric layer, the dielectric layer itself, or grain boundaries of a polycrystalline structure. Referring to FIG. 2, when the n-channel MOSFET is turned on under applied voltage, negatively charged electrons e drift toward a drain at a bottom, where an externally applied potential is high (move in a direction opposite to an electric field), while positively charged holes h drift toward a gate or source at a top, where an applied potential is low (move in a direction of the electric field). Because drift velocity of the holes h is much slower than that of the electrons e, corresponding induced electric charges (IEC) may be generated at the gate. With continuous accumulation of the IEC, the device may become permanently turned on (or off), resulting in device failure. This phenomenon is known as a cumulative received dose effect or a total ionizing dose (TID) effect under long-term irradiation. In contrast, a single event effect (SEE) under short-term irradiation refers to a phenomenon when a single high-energy particle (usually a heavy ion or proton) hits an oxide layer or a semiconductor of the electronic device, causing ionization of atoms in a local area. This results in generation of a large number of charges, which are transmitted in the device and trapped in the defect structures.

To prevent semiconductor device failure in a high-radiation environment, which may result in a problem such as a nuclear safety incident or space system malfunction, it is crucial to determine an extent of degradation caused by radiation energy damage to the device and radiation resistance of the device. In view of the foregoing, radiation hardening (Rad-Hard) has been applied in recent years to most semiconductor electronic devices that are susceptible to radiation damage to reduce their vulnerability to the radiation damage. For example, a cavity can be created or a highly doped boron layer (deep boron layer, DBL) can be embedded in a semiconductor device using a special manufacturing process to trap holes generated after irradiation, thereby preventing the holes from being trapped in defect structures and causing damage. However, the former technique (cavity) suffers from low yield in mass production due to a wafer bonding process, while the latter technique (DBL) is less effective in Rad-Hard than the former technique. Furthermore, the aforementioned conventional techniques not only present manufacturing challenges but also have limitations in effectiveness of radiation resistance. Accordingly, there remains an unresolved problem as to how to effectively enhance Rad-Hard in mass-produced semiconductor devices to improve TID and SEE conditions.

### SUMMARY OF THE DISCLOSURE

A main object of the present disclosure is to provide a superjunction metal-oxide-semiconductor field-effect transistor (MOSFET) with effectively enhanced radiation hardening (Rad-Hard).

To achieve the aforementioned object, in the present disclosure, a superjunction MOSFET includes a substrate, an N-type drift layer, a plurality of P-type columnar regions, a plurality of channel regions, and a plurality of PIN diodes. Mainly, in the present disclosure, the PIN diodes are formed in the N-type drift layer through ion implantation, wherein each of the PIN diodes includes an N-type semiconductor and a P-type semiconductor with high doping concentrations. This eliminates a need for a wafer bonding process with low yield. Furthermore, the high concentration doping allows a thinner I-type junction to be formed between the N-type semiconductor and the P-type semiconductor, resulting in a better quantum tunneling effect. This facilitates capturing of holes after irradiation, thereby enhancing Rad-Hard. In addition, each of the PIN diodes can be embedded at different positions within the N-type drift layer, resulting in varying Rad-Hard effectiveness and on-resistance (RDS(on)), thereby meeting various user requirements.

### BRIEF DESCRIPTION OF THE DRAWINGS

FIG. 1 is a schematic diagram illustrating a conventional metal-oxide-semiconductor field-effect transistor (MOSFET) and radiation rays.

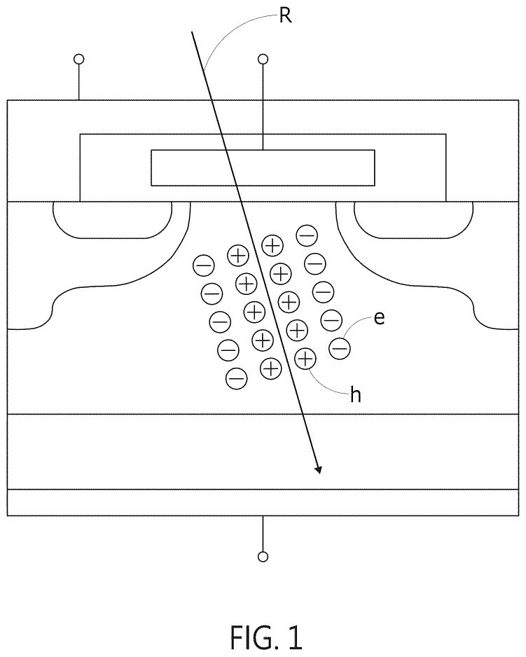

FIG. 2 is a schematic diagram illustrating the conventional MOSFET after irradiation with the radiation rays.

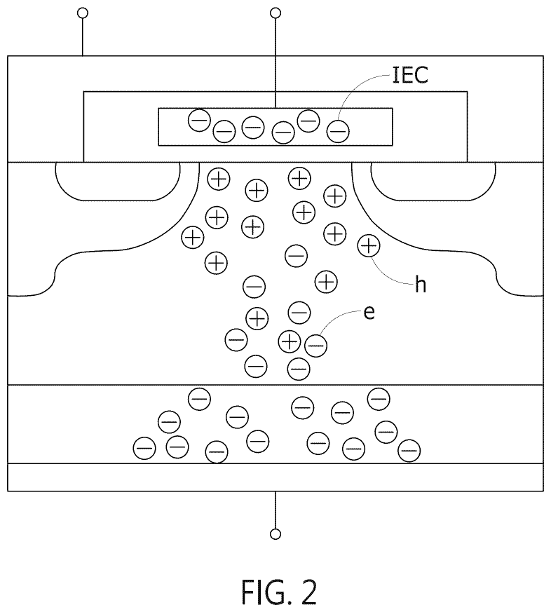

FIG. 3 is a schematic diagram illustrating a structure according to the present disclosure.

FIG. 4 is a schematic diagram (1) illustrating a structure according to an embodiment of the present disclosure.

FIG. 5 is a schematic diagram of implementation according to the present disclosure.

FIG. 6 is an experimental data chart (1) according to the present disclosure.

FIG. 7 is an experimental data chart (2) according to the present disclosure.

FIG. 8 is a schematic diagram (2) illustrating a structure according to an embodiment of the present disclosure.

FIG. 9 is a schematic diagram (3) illustrating a structure according to an embodiment of the present disclosure.

FIG. 10 is a schematic diagram (1) illustrating a structure using SiC material according to the present disclosure.

FIG. 11 is a schematic diagram (2) illustrating a structure using SiC material according to the present disclosure.

FIG. 12 is a schematic diagram (1) illustrating a P-channel type structure according to the present disclosure.

FIG. 13 is a schematic diagram (2) illustrating a P-channel type structure according to the present disclosure.

### DETAILED DESCRIPTION OF PREFERRED EMBODIMENTS

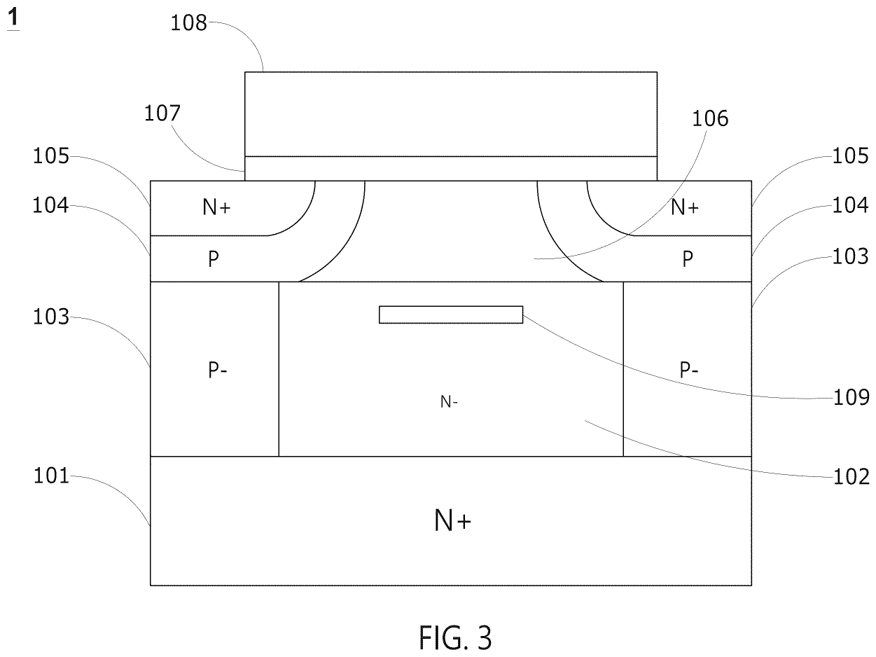

Referring to FIG. 3, in the present disclosure, a superjunction metal-oxide-semiconductor field-effect transistor (MOSFET) 1 with a structure arranged with a plurality of vertical PN junctions is employed. This design maintains breakdown voltage while reducing on-resistance (RDS(on)) and gate charges Qg, thereby addressing a problem of increased drift layer thickness and increased on-resistance, which occur when breakdown voltage of a planar MOSFET increases. The superjunction MOSFET 1 in the present disclosure includes a substrate 101 doped with an N-type conduction agent at a high doping concentration to serve as a drain for conduction; an N-type drift layer 102 implanted with the N-type conduction agent at a low doping concentration through ion implantation, and formed over the substrate 101; a plurality of P-type columnar regions 103 implanted with a P-type conduction agent at a low doping concentration through ion implantation after a lithography process on the N-type drift layer 102, and formed over the substrate 101 and within the N-type drift layer 102, such that the P-type columnar regions 103 are parallel to the N-type drift layer 102, forming a plurality of PN junctions; a plurality of P-type well regions 104, wherein each of the P-type well regions 104 is implanted with the P-type conduction agent and formed over the respective P-type columnar region 103; a plurality of N-type source regions 105, wherein each of the N-type source regions 105 is implanted with the N-type conduction agent at a high doping concentration and formed within the respective P-type well region 104; a plurality of channel regions 106, wherein each of the channel regions 106 is implanted with the N-type conduction agent and formed over the N-type drift layer 102 and between the respective P-type well regions 104; a plurality of dielectric layers 107, wherein each of the dielectric layers 107 is formed over the respective channel region 106 using a technique such as chemical vapor deposition (CVD); a plurality of gate layers 108, wherein each of the gate layers 108 is formed over the respective dielectric layer 107 and can be made of polysilicon, but the present disclosure is not limited thereto; and a plurality of I-type regions 109, wherein each of the I-type regions 109 is embedded in the N-type drift layer 102 and implanted with at least one doped ion. Each of the at least one doped ion can, for example, be an argon (Ar) ion. Because the I-type regions 109 have many quantum states, when the superjunction MOSFET 1 is irradiated, the quantum states in the I-type regions 109 can absorb holes h generated after irradiation. Thus, the use of I-type regions 109 can effectively prevent the holes h from being trapped in defect structures of the transistor and reduce induced electric charges (IEC) accumulated at the gate that can lead to device failure.

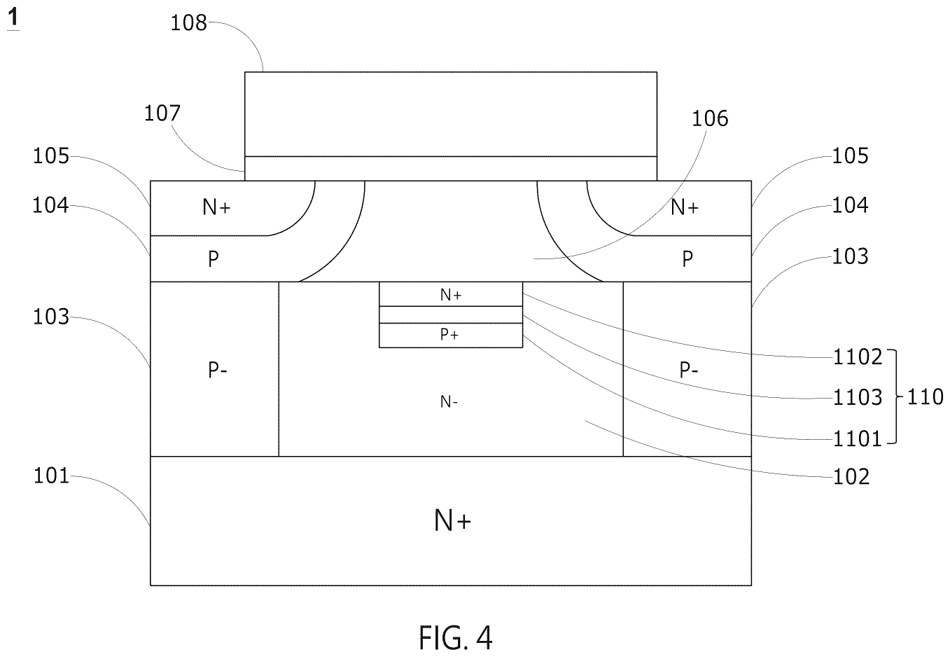

Referring to FIG. 4, the aforementioned I-type regions 109 can alternatively be replaced with PIN diodes 110, which are embedded in the N-type drift layer 102. Each of the PIN diodes 110 includes a P-type semiconductor 1101 and an N-type semiconductor 1102. The P-type semiconductor 1101 is embedded in the N-type drift layer 102 through ion implantation, and the N-type semiconductor 1102 is implanted and formed on the top of the P-type semiconductor 1101. The P-type semiconductor 1101 and the N-type semiconductor 1102 are in contact, forming an I-type junction 1103. When a forward voltage is applied to each of the PIN diodes 110, electrons pass from the N-type semiconductor 1102 through the I-type junction 1103 to the P-type semiconductor 1101 via a quantum tunneling effect, thereby capturing holes generated after irradiation. The higher the doping concentrations of the P-type semiconductor 1101 and the N-type semiconductor 1102, the more quantum states exist at the I-type junction 1103 between the P-type semiconductor 1101 and the N-type semiconductor 1102. This results in an increased number of charge carriers (electrons or holes) entering a conduction band, allowing more electrons to tunnel into the P-type semiconductor 1101. Additionally, the I-type junction 1103 is selectively formed through ion implantation using a dopant. The dopant can, for example, be at least one Ar ion. The at least one Ar ion is implanted between the P-type semiconductor 1101 and the N-type semiconductor 1102, increasing the number of quantum states at the I-type junction 1103.

Moreover, the higher the doping concentrations of the P-type semiconductor 1101 and the N-type semiconductor 1102, the thinner the thickness of the I-type junction 1103 formed at their contact. Thickness of the N-type drift layer 102, the P-type columnar regions 103, the P-type semiconductors 1101, and the N-type semiconductors 1102 can be adjusted according to desired breakdown voltage of the superjunction MOSFET 1. The P-type conduction agent can, for example, be boron (B) ions, indium (In) ions, or gallium (Ga) ions, and the N-type conduction agent can, for example, be phosphorus (P) ions, arsenic (As) ions, or antimony (Sb) ions, but the present disclosure is not limited thereto. The N-type conduction agent (as indicated by “N” in the figure) and the P-type conduction agent (as indicated by “P” in the figure) have opposite electrical polarities. Additionally, a concentration of each of the conduction agents is denoted using a symbol “+” (a plus sign in mathematical notation) or “−” (a minus sign in mathematical notation), where “+” indicates a higher relative concentration, “−” indicates a lower relative concentration, and absence of “+” or “−” represents a relative concentration between the two.

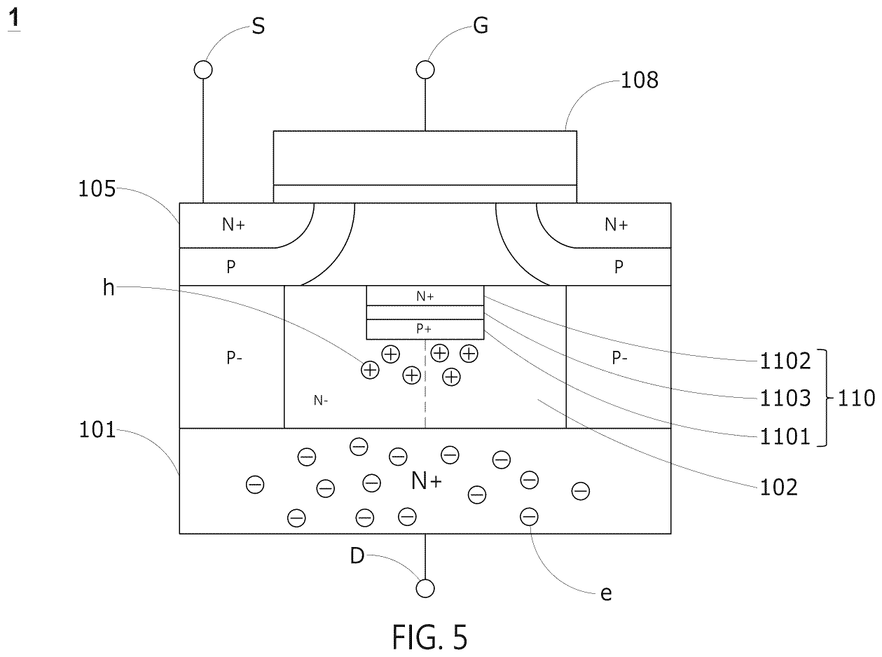

Based on the above, referring to FIG. 5, after the superjunction MOSFET 1 in the present disclosure is irradiated, electrons e generated by excitation drift along a direction opposite to the electric field toward the substrate 101 which is electrically connected to a drain terminal D, while generated holes h drift along a direction of the electric field toward each of the gate layers 108 which is electrically connected to a gate terminal G. The holes h are attracted by the electrons at the I-type junction 1103 of each of the PIN diodes 110 and are subsequently captured and filled. Thus, each of the PIN diodes 110 can be used to absorb the holes h generated after irradiation, effectively preventing the holes h from being trapped in defect structures of the transistor and reducing IEC accumulated at the gate that can lead to device failure.

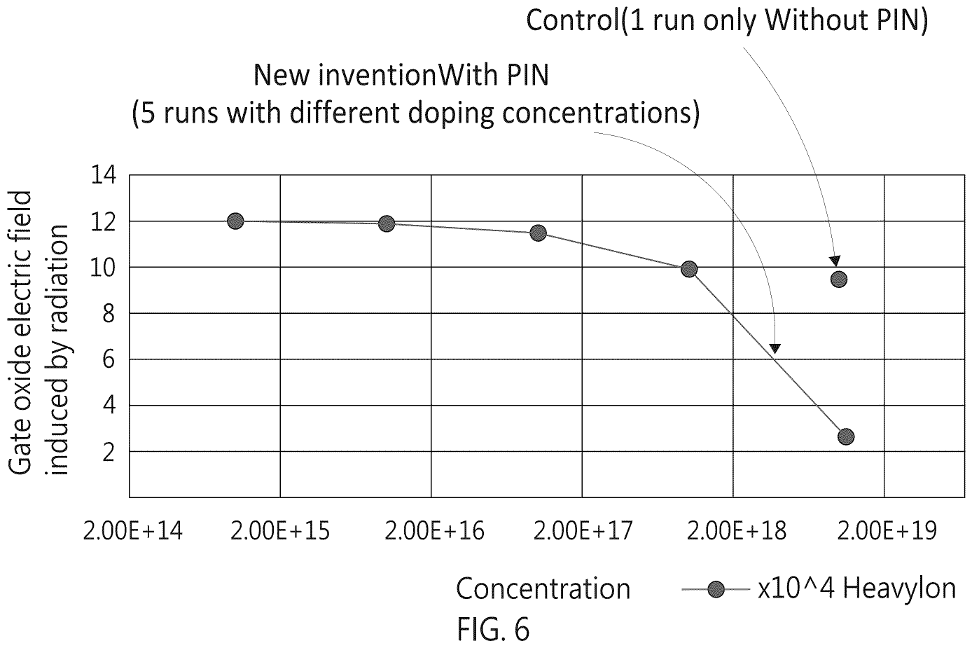

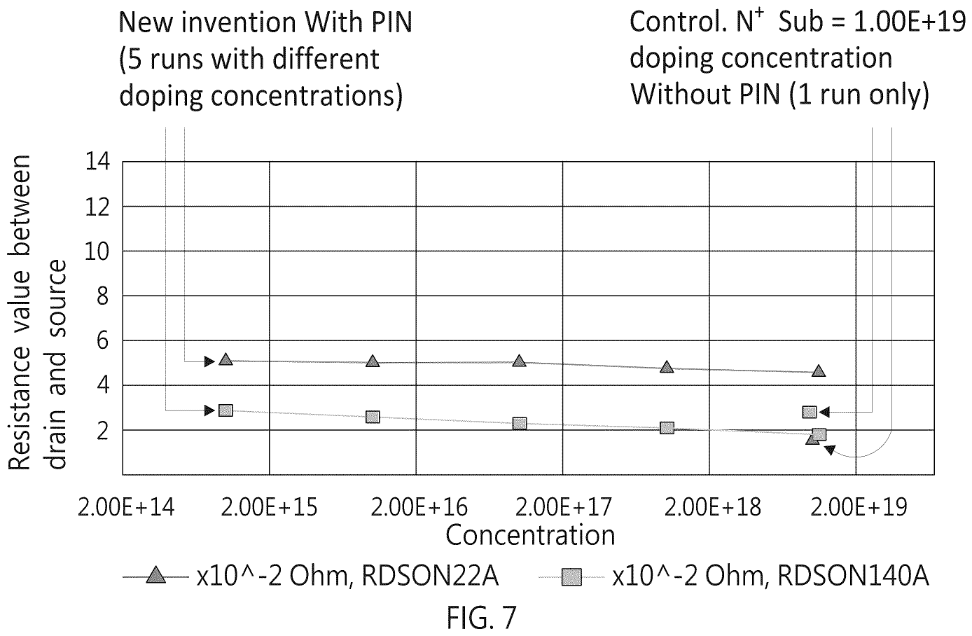

Referring to FIG. 6 in conjunction with FIG. 5, in the present disclosure, each the PIN diodes 110 can be formed through ion implantation at different doping concentrations (1E15 cm⁻³, 1E16 cm⁻³, 1E17 cm⁻³, 1E18 cm⁻³, 1E19 cm⁻³). When the doping concentrations of the P-type semiconductor 1101 and the N-type semiconductor 1102 are 1E19 cm⁻³, an induced electric field at the gate G generated after irradiation can be effectively reduced. This indicates that at the doping concentration of 1E19 cm⁻³, energy levels of intra-band and inter-band quantum states generated at the I-type junction 1103 can absorb tunneling electrons between the P-type semiconductor 1101 and the N-type semiconductor 1102. This, combined with an effect of overlapping synchronized quantum states, results in significantly improved efficiency of hole h absorption. The number of absorbed holes h at the doping concentration of 1E19 cm⁻³ is more than five times greater than that at the doping concentration of 1E15 cm⁻³. Additionally, referring to FIG. 7, compared to a transistor without the embedded PIN diodes 110, the superjunction MOSFET 1 in the present disclosure exhibits different performance of on-resistance (RDS(on)) at high current and low current. In the conventional transistor without the embedded PIN diodes 110, on-resistance at high current (140A) is higher than that at low current (22A), resulting in increased power loss at high current. In contrast, in the superjunction MOSFET 1 in the present disclosure, on-resistance at the high current (140A) is lower than that at the low current (22A), indicating that power consumption of the device is lower at high current, thereby enhancing energy conversion efficiency.

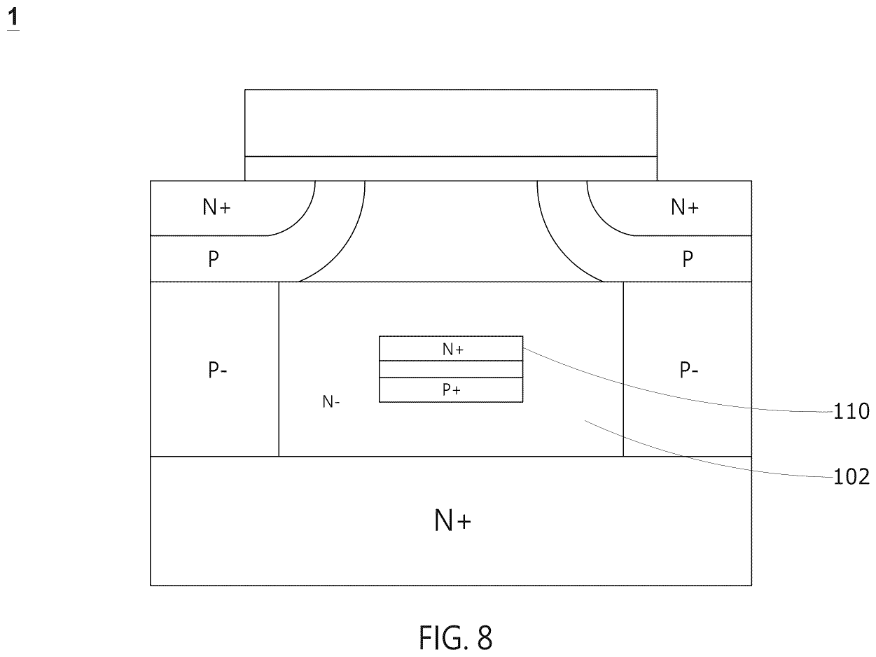

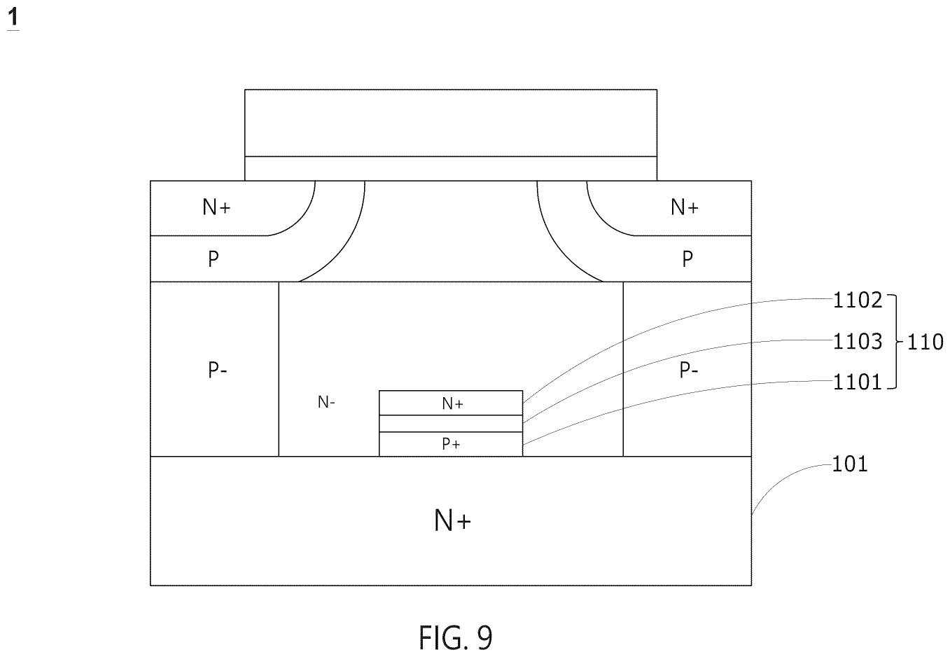

Referring to FIG. 8 in conjunction with FIG. 4, the superjunction MOSFET 1 in the present disclosure provides varying radiation-hardening effectiveness depending on an embedded position of each of the PIN diodes 110. When each of the PIN diodes 110 is implanted at an upper position within the N-type drift layer 102 (as illustrated in FIG. 4) and the respective channel region 106 is implanted over the N-type semiconductor 1102 of each of the PIN diodes 110, because holes generated after circuit conduction drift toward the respective gate layer 108, optimal hole-trapping efficiency is achieved. However, this configuration exhibits relatively higher on-resistance. When each of the PIN diodes 110 is implanted at a middle position within the N-type drift layer 102 (as illustrated in FIG. 8), although hole-trapping efficiency of each of the PIN diodes 110 is not as high as that achieved at the upper position within the N-type drift layer 102, on-resistance is relatively lower. Referring to FIG. 9, when each of the PIN diodes 110 is implanted at a lower position within the N-type drift layer 102, and the P-type semiconductor 1101 is implanted and formed over the substrate 101, hole-trapping efficiency of each of the PIN diodes 110 is the lowest among the three configurations, yet this configuration has the lowest on-resistance and minimal power loss. Users can implant each of the PIN diodes 110 at a suitable position according to their requirements to effectively capture holes generated after irradiation while reducing power loss.

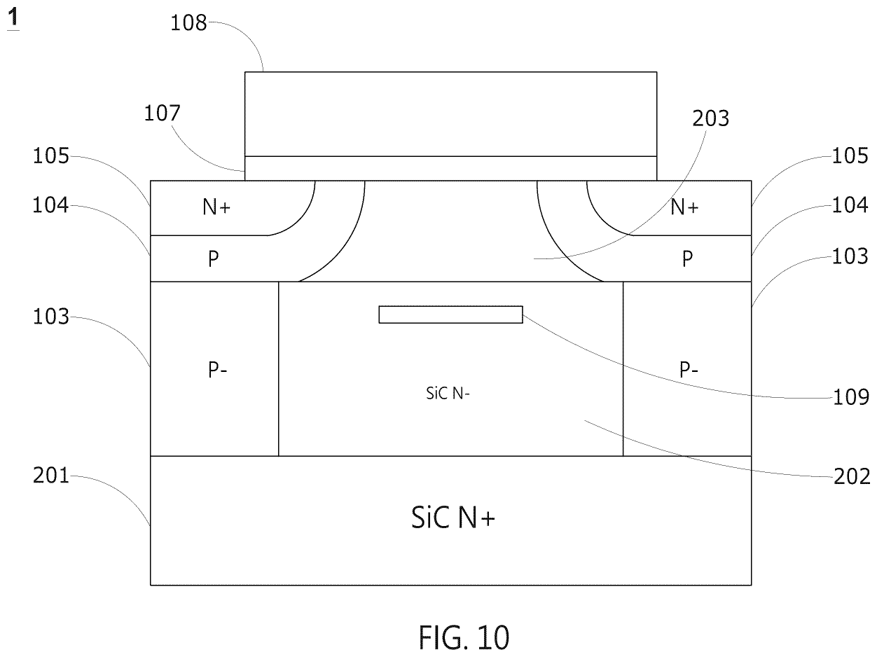

Referring to FIG. 10, silicon carbide (SiC) material may alternatively be used in an embodiment as disclosed in the present disclosure. As illustrated in the figure, the superjunction MOSFET 1 in the present disclosure may alternatively include an SiC substrate 201 formed from the SiC material, wherein the SiC substrate 201 is doped with an N-type conduction agent at a high doping concentration to serve as a drain for conduction; an N-type SiC drift layer 202 implanted with the N-type conduction agent at a low doping concentration through ion implantation, and formed over the SiC substrate 201; a plurality of P-type columnar regions 103 implanted with a P-type conduction agent at a low doping concentration through ion implantation after a lithography process on the N-type SiC drift layer 202, and formed over the SiC substrate 201 and within the N-type SiC drift layer 202, such that the P-type columnar regions 103 are parallel to the N-type SiC drift layer 202, forming a plurality of PN junctions; a plurality of P-type well regions 104, wherein each of the P-type well regions 104 is implanted with the P-type conduction agent and formed over the respective P-type columnar region 103; a plurality of N-type source regions 105, wherein each of the N-type source regions 105 is implanted with the N-type conduction agent at a high doping concentration and formed within the respective P-type well region 104; a plurality of SiC channel regions 203, wherein each of the SiC channel regions 203 is implanted with the N-type conduction agent and formed over the N-type SiC drift layer 202 and between the respective P-type well regions 104; a plurality of dielectric layers 107, wherein each of the dielectric layers 107 is formed over the respective SiC channel region 203 using a technique such as CVD; a plurality of gate layers 108, wherein each of the gate layers 108 is formed over the respective dielectric layer 107 and can be made of polysilicon, but the present disclosure is not limited thereto; and a plurality of I-type regions 109, wherein each of the I-type regions 109 is embedded in the N-type SiC drift layer 202 and implanted with at least one doped ion. Each of the at least one doped ion can, for example, be an Ar ion. Because the I-type regions 109 have many quantum states, when the superjunction MOSFET 1 is irradiated, the quantum states in the I-type regions 109 can absorb holes h generated after irradiation. Thus, the use of I-type regions 109 can effectively prevent the holes h from being trapped in defect structures of the transistor and reduce IEC accumulated at the gate that can lead to device failure.

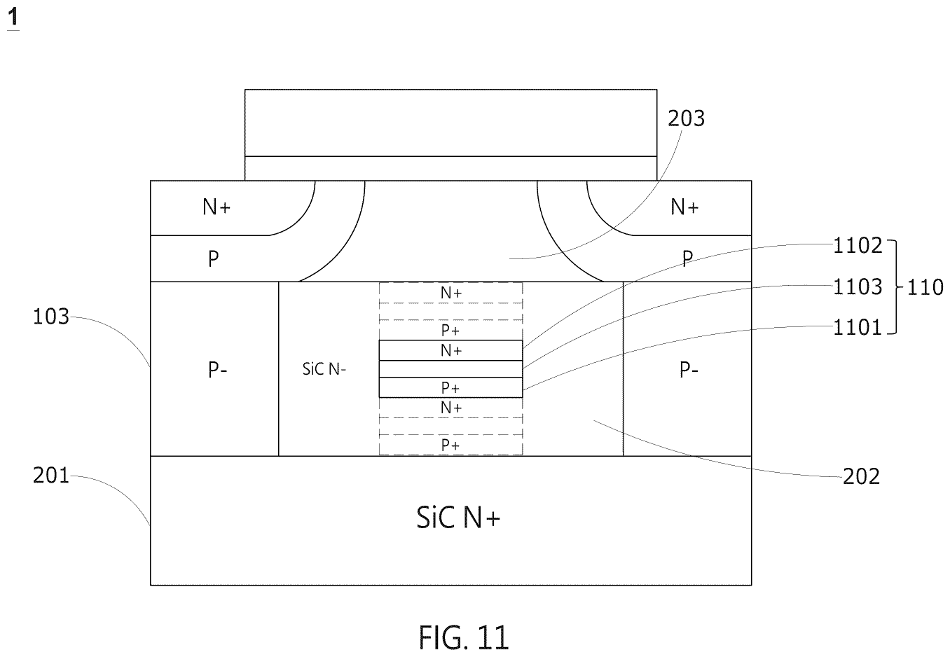

Referring to FIG. 11, the aforementioned I-type regions 109 can alternatively be replaced with PIN diodes 110, which are embedded in the N-type SiC drift layer 202. Each of the PIN diodes 110 includes a P-type semiconductor 1101 and an N-type semiconductor 1102. The P-type semiconductor 1101 is embedded in the N-type SiC drift layer 202 through ion implantation, and the N-type semiconductor 1102 is implanted and formed on the top of the P-type semiconductor 1101. The P-type semiconductor 1101 and the N-type semiconductor 1102 are in contact, forming an I-type junction 1103. When a forward voltage is applied to each of the PIN diodes 110, electrons pass from the N-type semiconductor 1102 through the I-type junction 1103 to the P-type semiconductor 1101 via a quantum tunneling effect, thereby capturing holes generated after irradiation. The higher the doping concentrations of the P-type semiconductor 1101 and the N-type semiconductor 1102, the more quantum states exist at the I-type junction 1103 between the P-type semiconductor 1101 and the N-type semiconductor 1102. This results in an increased number of charge carriers (electrons or holes) entering a conduction band, allowing more electrons to tunnel into the P-type semiconductor 1101. Additionally, the I-type junction 1103 is selectively formed through ion implantation using a dopant. The dopant can, for example, be at least one Ar ion. The at least one Ar ion is implanted between the P-type semiconductor 1101 and the N-type semiconductor 1102, increasing the number of quantum states at the I-type junction 1103. Moreover, the higher the doping concentrations of the P-type semiconductor 1101 and the N-type semiconductor 1102, the thinner the thickness of the I-type junction 1103 formed at their contact. Thickness of the N-type SiC drift layer 202, the P-type columnar regions 103, the P-type semiconductors 1101, and the N-type semiconductors 1102 can be adjusted according to desired breakdown voltage of the superjunction MOSFET 1. The P-type conduction agent can, for example, be B ions, In ions, or Ga ions, and the N-type conduction agent can, for example, be P ions, As ions, or Sb ions, but the present disclosure is not limited thereto. The N-type conduction agent (as indicated by “N” in the figure) and the P-type conduction agent (as indicated by “P” in the figure) have opposite electrical polarities. Additionally, a concentration of each of the conduction agents is denoted using a symbol “+” (a plus sign in mathematical notation) or “−” (a minus sign in mathematical notation), where “+” indicates a higher relative concentration, “−” indicates a lower relative concentration, and absence of “+” or “−” represents a relative concentration between the two.

Based on the above, the superjunction MOSFET 1 in the present disclosure provides varying radiation-hardening effectiveness depending on an embedded position of each of the PIN diodes 110. When each of the PIN diodes 110 is implanted at an upper position within the N-type SiC drift layer 202 and the respective SiC channel region 203 is implanted over the N-type semiconductor 1102 of each of the PIN diodes 110, because holes generated after circuit conduction drift toward the respective gate layer 108, optimal hole-trapping efficiency is achieved. However, this configuration exhibits relatively higher on-resistance. When each of the PIN diodes 110 is implanted at a middle position within the N-type SiC drift layer 202, although hole-trapping efficiency of each of the PIN diodes 110 is not as high as that achieved at the upper position within the N-type SiC drift layer 202, on-resistance is relatively lower. When each of the PIN diodes 110 is implanted at a lower position within the N-type SiC drift layer 202, and the P-type semiconductor 1101 is implanted and formed over the SiC substrate 201, hole-trapping efficiency of each of the PIN diodes 110 is the lowest among the three configurations, yet this configuration has the lowest on-resistance and minimal power loss. Users can implant each of the PIN diodes 110 at a suitable position according to their requirements to effectively capture holes generated after irradiation while reducing power loss.

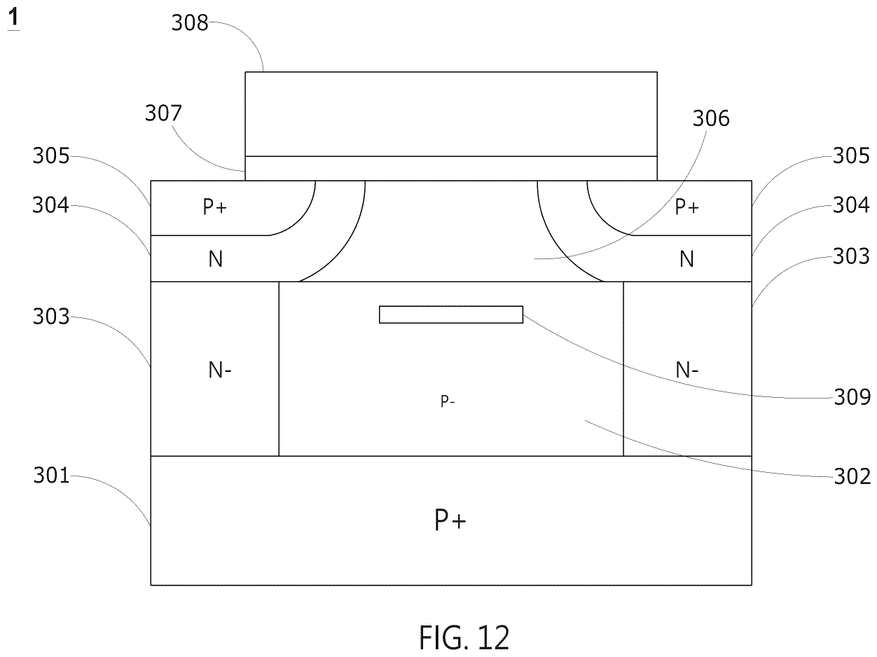

Referring to FIG. 12, the aforementioned superjunction MOSFETs are illustrated by way of example using N-channel MOSFET embodiments, and may alternatively be illustrated using P-channel MOSFET embodiments. As illustrated in the figure, the superjunction MOSFET 1 in the present disclosure includes a substrate 301 doped with an P-type conduction agent at a high doping concentration to serve as a drain for conduction, wherein the substrate 301 can be made of silicon (Si) or SiC, but the present disclosure is not limited thereto; a P-type drift layer 302, wherein the P-type drift layer 302 can made of Si or SiC, but the present disclosure is not limited thereto, and wherein the P-type drift layer 302 is implanted with the P-type conduction agent at a low doping concentration through ion implantation, and formed over the substrate 301; a plurality of N-type columnar regions 303 implanted with an N-type conduction agent at a low doping concentration through ion implantation after a lithography process on the P-type drift layer 302, and formed over the substrate 301 and within the P-type drift layer 302, such that the N-type columnar regions 303 are parallel to the P-type drift layer 302, forming a plurality of PN junctions; a plurality of N-type well regions 304, wherein each of the N-type well regions 304 is implanted with the N-type conduction agent and formed over the respective N-type columnar region 303; a plurality of P-type source regions 305, wherein each of the P-type source regions 305 is implanted with the P-type conduction agent at a high doping concentration and formed within the respective N-type well region 304; a plurality of channel regions 306, wherein each of the channel regions 306 is made of Si or SiC, but the present disclosure is not limited thereto, and wherein each of the channel regions 306 is implanted with the P-type conduction agent and formed over the P-type drift layer 302 and between the respective N-type well regions 304; a plurality of dielectric layers 307, wherein each of the dielectric layers 307 is formed over the respective channel region 306 using a technique such as CVD; a plurality of gate layers 308, wherein each of the gate layers 308 is formed over the respective dielectric layer 307 and can be made of polysilicon, but the present disclosure is not limited thereto; and a plurality of I-type regions 309, wherein each of the I-type regions 309 is embedded in the P-type drift layer 302 and implanted with at least one doped ion. Each of the at least one doped ion can, for example, be an Ar ion. Because the I-type regions 309 have many quantum states, when the superjunction MOSFET 1 is irradiated, the quantum states in the I-type regions 309 can absorb holes h generated after irradiation. Thus, the use of I-type regions 309 can effectively prevent the holes h from being trapped in defect structures of the transistor and reduce IEC accumulated at the gate that can lead to device failure.

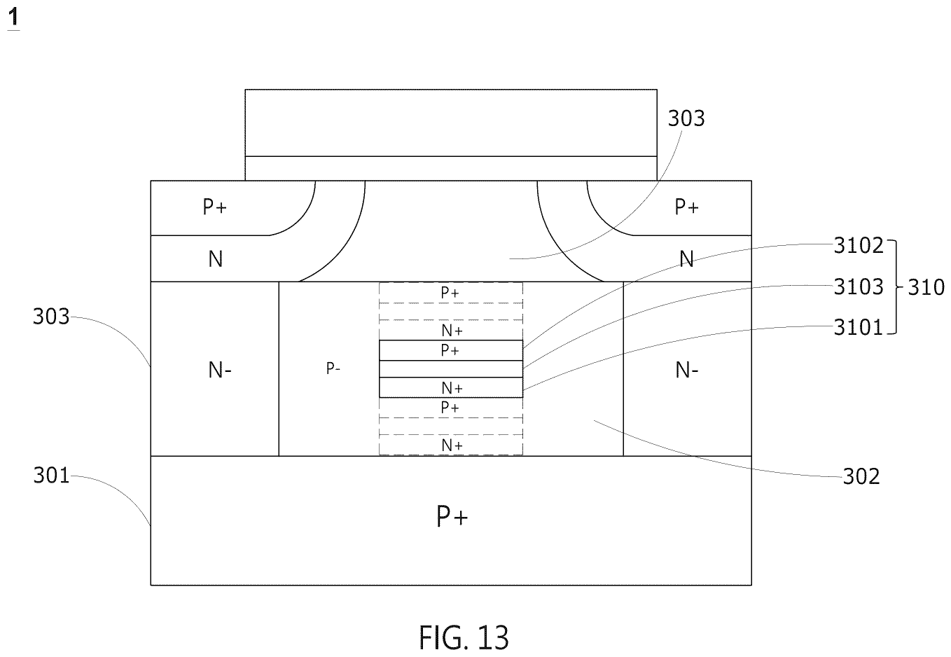

Referring to FIG. 13, the aforementioned I-type regions 309 can alternatively be replaced with NIP diodes 310, which are embedded in the P-type drift layer 302. Each of the NIP diodes 310 includes an N-type semiconductor 3101 and a P-type semiconductor 3102. The N-type semiconductor 3101 is embedded in the P-type drift layer 302 through ion implantation, and the P-type semiconductor 3102 is implanted and formed on the top of the N-type semiconductor 3101. The N-type semiconductor 3101 and the P-type semiconductor 3102 are in contact, forming an I-type junction 3103. When a forward voltage is applied to each of the NIP diodes 310, electrons pass from the P-type semiconductor 3102 through the I-type junction 3103 to the N-type semiconductor 3101 via a quantum tunneling effect, thereby capturing holes h generated after irradiation. The higher the doping concentrations of the N-type semiconductor 3101 and the P-type semiconductor 3102, the more quantum states exist at the I-type junction 3103 between the N-type semiconductor 3101 and the P-type semiconductor 3102. This results in an increased number of charge carriers (electrons or holes) entering a conduction band, allowing more electrons to tunnel into the N-type semiconductor 3101. Additionally, the I-type junction 3103 is selectively formed through ion implantation using a dopant. The dopant can, for example, be at least one Ar ion. The at least one Ar ion is implanted between the N-type semiconductor 3101 and the P-type semiconductor 3102, increasing the number of quantum states at the I-type junction 3103. Moreover, the higher the doping concentrations of the N-type semiconductor 3101 and the P-type semiconductor 3102, the thinner the thickness of the I-type junction 3103 formed at their contact. Thickness of the P-type drift layer 302, the N-type columnar regions 303, the N-type semiconductors 3101, and the P-type semiconductors 3102 can be adjusted according to desired breakdown voltage of the superjunction MOSFET 1. The P-type conduction agent can, for example, be B ions, In ions, or Ga ions, and the N-type conduction agent can, for example, be P ions, As ions, or Sb ions, but the present disclosure is not limited thereto. The N-type conduction agent (as indicated by “N” in the figure) and the P-type conduction agent (as indicated by “P” in the figure) have opposite electrical polarities. Additionally, a concentration of each of the conduction agents is denoted using a symbol “+” or “−”, where “+” indicates a higher relative concentration, “−” indicates a lower relative concentration, and absence of “+” or “−” represents a relative concentration between the two.

Based on the above, the superjunction MOSFET 1 in the present disclosure provides varying radiation-hardening effectiveness depending on an embedded position of each of the NIP diodes 310. When each of the NIP diodes 310 is implanted at an upper position within the P-type drift layer 302 and the respective channel region 306 is implanted over the P-type semiconductor 3102 of each of the NIP diodes 310, because holes generated after circuit conduction drift toward the respective gate layer 308, optimal hole-trapping efficiency is achieved. However, this configuration exhibits relatively higher on-resistance. When each of the NIP diodes 310 is implanted at a middle position within the P-type drift layer 302, although hole-trapping efficiency of each of the NIP diodes 310 is not as high as that achieved at the upper position within the P-type drift layer 302, on-resistance is relatively lower. When each of the NIP diodes 310 is implanted at a lower position within the P-type drift layer 302, and the N-type semiconductor 3101 is implanted and formed over the substrate 301, hole-trapping efficiency of each of the NIP diodes 310 is the lowest among the three configurations, yet this configuration has the lowest on-resistance and minimal power loss. Users can implant each of the NIP diodes 310 at a suitable position according to their requirements to effectively capture holes generated after irradiation while reducing power loss.

As mentioned above, mainly, in a superjunction MOSFET of the present disclosure, PIN diodes are embedded within an N-type drift layer through ion implantation. In each of the PIN diodes, both a P-type semiconductor and an N-type semiconductor are highly doped, forming an I-type junction when the two are in contact. This configuration effectively captures holes generated after irradiation through a quantum tunneling effect. This not only simplifies a device manufacturing process but also significantly enhances radiation hardening (Rad-Hard) under mass production of semiconductor devices, thereby improving conditions of total ionizing dose (TID) and single event effect (SEE). Accordingly, upon implementation, the present disclosure indeed achieves an object of providing a superjunction MOSFET with effectively enhanced Rad-Hard.

The above is only the preferred embodiments of the present disclosure, and is not intended to limit the present disclosure to the forms disclosed. Any modifications, equivalent alternatives, and improvements made within the spirit and the scope of present disclosure by persons skilled in the art should be included in the scope of claims of the present disclosure.

### REFERENCE NUMERALS IN DRAWINGS

1 a superjunction MOSFET
101 a substrate
102 an N-type drift layer
103 a P-type columnar region
104 a P-type well region
105 an N-type source region
106 a channel region
107 a dielectric layer
108 a gate layer
109 an I-type region
110 a PIN diode
1101 a P-type semiconductor
1102 an N-type semiconductor
1103 an I-type junction
201 a SiC substrate
202 an N-type SiC drift layer
203 a SiC channel region
IEC induced electric charges
301 a substrate
302 a P-type drift layer
303 an N-type columnar region
304 an N-type well region
305 a P-type source region
306 a channel region
307 a dielectric layer
308 a gate layer
309 an I-type region
310 an NIP diode
3101 an N-type semiconductor
3102 a P-type semiconductor
3103 an I-type junction
R a radiation ray
h holes
e electrons
G a gate terminal
D a drain terminal
S a source terminal

What is claimed is:

1. A superjunction metal-oxide-semiconductor field-effect transistor (MOSFET), comprising:
a substrate doped with an N-type conduction agent at a high doping concentration;
an N-type drift layer doped with the N-type conduction agent at a low doping concentration and extending over the substrate;
a plurality of P-type columnar regions, wherein each of the P-type columnar regions is doped with a P-type conduction agent at a low doping concentration and extends within the N-type drift layer;
a plurality of P-type well regions, wherein each of the P-type well regions is implanted with the P-type conduction agent and formed over the respective P-type columnar region;
a plurality of N-type source regions, wherein each of the N-type source regions is implanted with the N-type conduction agent at a high doping concentration and formed within the respective P-type well region;
a plurality of channel regions, wherein each of the channel regions is implanted with the N-type conduction agent and formed over the N-type drift layer and between the respective P-type well regions;
a plurality of dielectric layers, wherein each of the dielectric layers is formed over the respective channel region;
a plurality of gate layers, wherein each of the gate layers is formed over the respective dielectric layer; and
a plurality of I-type regions, wherein each of the I-type regions is embedded in the N-type drift layer and implanted with at least one doped ion.

2. The superjunction MOSFET of claim 1, wherein each of the at least one doped ion in each of the I-type regions is an argon ion.

3. The superjunction MOSFET of claim 1, wherein material of the substrate, the N-type drift layer, and the channel regions is silicon (Si) or silicon carbide (SiC).

4. A superjunction metal-oxide-semiconductor field-effect transistor (MOSFET), comprising:
a substrate doped with an N-type conduction agent at a high doping concentration;
an N-type drift layer doped with the N-type conduction agent at a low doping concentration and extending over the substrate;
a plurality of P-type columnar regions, wherein each of the P-type columnar regions is doped with a P-type conduction agent at a low doping concentration and extends within the N-type drift layer;
a plurality of P-type well regions, wherein each of the P-type well regions is implanted with the P-type conduction agent and formed over the respective P-type columnar region;
a plurality of N-type source regions, wherein each of the N-type source regions is implanted with the N-type conduction agent at a high doping concentration and formed within the respective P-type well region;
a plurality of channel regions, wherein each of the channel regions is implanted with the N-type conduction agent and formed over the N-type drift layer and between the respective P-type well regions;
a plurality of dielectric layers, wherein each of the dielectric layers is formed over the respective channel region;
a plurality of gate layers, wherein each of the gate layers is formed over the respective dielectric layer; and
a plurality of PIN diodes, wherein each of the PIN diodes is embedded in the N-type drift layer, and wherein each of the PIN diodes comprises a P-type semiconductor and an N-type semiconductor, the N-type semiconductor is implanted and formed on the top of the P-type semiconductor, and the P-type semiconductor and the N-type semiconductor are in contact, forming an I-type junction.

5. The superjunction MOSFET of claim 4, wherein each P-type semiconductor of the PIN diodes is implanted and formed with the P-type conduction agent at a doping concentration greater than or equal to 1E19 cm⁻³, and each N-type semiconductor of the PIN diodes is implanted and formed with the N-type conduction agent at a doping concentration greater than or equal to 1E19 cm⁻³.

6. The superjunction MOSFET of claim 4, wherein material of the substrate, the N-type drift layer, and the channel regions is silicon (Si) or silicon carbide (SiC).

7. The superjunction MOSFET of claim 4, wherein the P-type conduction agent is one of boron ions, indium ions, or gallium ions, and the N-type conduction agent is one of phosphorus ions, arsenic ions, or antimony ions.

8. The superjunction MOSFET of claim 4, wherein at least one of the PIN diodes is embedded in the N-type drift layer, with an embedded position of each of the at least one of the PIN diodes located at a middle of the N-type drift layer.

9. The superjunction MOSFET of claim 4, wherein at least one of the PIN diodes is embedded in the N-type drift layer, with the respective channel region implanted over the N-type semiconductor of each of the at least one of the PIN diodes.

10. The superjunction MOSFET of claim 4, wherein at least one of the PIN diodes is embedded in the N-type drift layer, with the P-type semiconductor of each of the at least one of the PIN diodes implanted and formed over the substrate.

11. The superjunction MOSFET of claim 4, wherein the I-type junction is selectively formed through ion implantation using a dopant.

12. The superjunction MOSFET of claim 11, wherein the dopant is at least one argon ion.

13. A superjunction metal-oxide-semiconductor field-effect transistor (MOSFET), comprising:
a substrate doped with a P-type conduction agent at a high doping concentration;
a P-type drift layer doped with the P-type conduction agent at a low doping concentration and extending over the substrate;
a plurality of N-type columnar regions, wherein each of the N-type columnar regions is doped with an N-type conduction agent at a low doping concentration and extends within the P-type drift layer;
a plurality of N-type well regions, wherein each of the N-type well regions is implanted with the N-type conduction agent and formed over the respective N-type columnar region;
a plurality of P-type source regions, wherein each of the P-type source regions is implanted with the P-type conduction agent at a high doping concentration and formed within the respective N-type well region;
a plurality of channel regions, wherein each of the channel regions is implanted with the P-type conduction agent and formed over the P-type drift layer and between the respective N-type well regions;
a plurality of dielectric layers, wherein each of the dielectric layers is formed over the respective channel region;
a plurality of gate layers, wherein each of the gate layers is formed over the respective dielectric layer; and
a plurality of I-type regions, wherein each of the I-type regions is embedded in the P-type drift layer and implanted with at least one doped ion.

14. The superjunction MOSFET of claim 13, wherein each of the at least one doped ion in each of the I-type regions is an argon ion.

15. The superjunction MOSFET of claim 13, wherein material of the substrate, the P-type drift layer, and the channel regions is silicon (Si) or silicon carbide (SiC).

16. A superjunction metal-oxide-semiconductor field-effect transistor (MOSFET), comprising:
a substrate doped with a P-type conduction agent at a high doping concentration;
a P-type drift layer doped with the P-type conduction agent at a low doping concentration and extending over the substrate;
a plurality of N-type columnar regions, wherein each of the N-type columnar regions is doped with an N-type conduction agent at a low doping concentration and extends within the P-type drift layer;
a plurality of N-type well regions, wherein each of the N-type well regions is implanted with the N-type conduction agent and formed over the respective N-type columnar region;
a plurality of P-type source regions, wherein each of the P-type source regions is implanted with the P-type conduction agent at a high doping concentration and formed within the respective N-type well region;
a plurality of channel regions, wherein each of the channel regions is implanted with the P-type conduction agent and formed over the P-type drift layer and between the respective N-type well regions;
a plurality of dielectric layers, wherein each of the dielectric layers is formed over the respective channel region;
a plurality of gate layers, wherein each of the gate layers is formed over the respective dielectric layer; and
a plurality of NIP diodes, wherein each of the NIP diodes is embedded in the P-type drift layer, and wherein each of the NIP diodes comprises an N-type semiconductor and a P-type semiconductor, the P-type semiconductor is implanted and formed on the top of the N-type semiconductor, and the N-type semiconductor and the P-type semiconductor are in contact, forming an I-type junction.

17. The superjunction MOSFET of claim 16, wherein material of the substrate, the P-type drift layer, and the channel regions is silicon (Si) or silicon carbide (SiC).

18. The superjunction MOSFET of claim 16, wherein the P-type conduction agent is one of boron ions, indium ions, or gallium ions, and the N-type conduction agent is one of phosphorus ions, arsenic ions, or antimony ions.

19. The superjunction MOSFET of claim 16, wherein at least one of the NIP diodes is embedded in the P-type drift layer, with an embedded position of each of the at least one of the NIP diodes located at a middle of the P-type drift layer.

20. The superjunction MOSFET of claim 16, wherein at least one of the NIP diodes is embedded in the P-type drift layer, with the respective channel region implanted over the P-type semiconductor of each of the at least one of the NIP diodes.

21. The superjunction MOSFET of claim 16, wherein at least one of the NIP diodes is embedded in the P-type drift layer, with the N-type semiconductor of each of the at least one of the NIP diodes implanted and formed over the substrate.

22. The superjunction MOSFET of claim 16, wherein the I-type junction is selectively formed through ion implantation using a dopant.

23. The superjunction MOSFET of claim 22, wherein the dopant is at least one argon ion.
